(19) United States
(12) Patent Application Publication
(10) Pub. No.: US 2026/0059838 A1
(43) Pub. Date: Feb. 26, 2026

(54) INTEGRATED CIRCUIT CELL HAVING GATE-CONDUCTOR SEGMENTS FORMED FROM A GATE-CONDUCTOR

(71) Applicant: TAIWAN SEMICONDUCTOR MANUFACTURING COMPANY, LTD., Hsinchu (TW)

(72) Inventors: Ming-Cheng SYU, Hsinchu (TW); Yu-Tao YANG, Hsinchu (TW); Liang Chuan CHANG, Hsinchu (TW); Wen-Shen CHOU, Hsinchu (TW)

(21) Appl. No.: 18/815,222

(22) Filed: Aug. 26, 2024

(51) Int. Cl. H01L 29/423; H01L 27/02; H01L 29/417

(52) U.S. Cl. CPC H10D 64/519; H10D 64/254; H10D 64/518; H10D 89/10

(57) ABSTRACT

An integrated circuit includes a first power line and a second power line extending in a first direction. An integrated circuit includes a column of three gate-conductor segments aligned along a second direction and bounded by the first power line and the second power line. The three gate-conductor segments include a middle gate-conductor segment between a first gate-conductor segment and a second gate-conductor segment. The first gate-conductor segment intersects a first-type active-region structure at a channel region of a first-type transistor. The second gate-conductor segment intersects a second-type active-region structure at a channel region of a second-type transistor.

### BACKGROUND

The recent trend in miniaturizing integrated circuits (ICs) has resulted in smaller devices which consume less power yet provide more functionality at higher speeds. The miniaturization process has also resulted in stricter design and manufacturing specifications as well as reliability challenges. Various electronic design automation (EDA) tools generate, optimize, and verify standard cell layout designs for integrated circuits while ensuring that the standard cell layout design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a layout diagram of an integrated circuit, in accordance with some embodiments.

FIG. 1B is a schematic of an integrated circuit formed based on the layout diagram of FIG. 1A, in accordance with some embodiments.

FIGS. 2A-2E are cross-sectional views of the circuit cell along various cutting planes as shown in FIG. 1A, in accordance with some embodiments.

FIG. 3A is a layout diagram of an integrated circuit, in accordance with some embodiments.

FIG. 3B is a schematic of an integrated circuit formed based on the layout diagram of FIG. 3A, in accordance with some embodiments.

FIGS. 4A-4E are cross-sectional views of the circuit cell along various cutting planes as shown in FIG. 3A, in accordance with some embodiments.

FIG. 5A is a layout diagram of an integrated circuit, in accordance with some embodiments.

FIG. 5B is a schematic of an integrated circuit formed based on the layout diagram of FIG. 5A, in accordance with some embodiments.

FIG. 6A is a layout diagram of an integrated circuit, in accordance with some embodiments.

FIG. 6B is a schematic of an integrated circuit formed based on the layout diagram of FIG. 6A, in accordance with some embodiments.

FIG. 7A is a layout diagram of an integrated circuit, in accordance with some embodiments.

FIG. 7B is a schematic of an integrated circuit formed based on the layout diagram of FIG. 7A, in accordance with some embodiments.

FIGS. 8A-8B are schematics of integrated circuits which are variations of the integrated circuit in FIG. 1B, in accordance with some embodiments.

FIGS. 9A-9B are flowcharts of methods of manufacturing an integrated circuit, in accordance with some embodiments.

FIG. 10 is a block diagram of an electronic design automation (EDA) system in accordance with some embodiments.

FIG. 11 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated circuit includes a first power line and a second power line extending in an X-direction at horizontal cell boundaries of a circuit cell. In some embodiments, the circuit cell includes a column of three gate-conductor segments aligned along the Y-direction and bounded by the first power line and the second power line. The column of three gate-conductor segments includes a middle gate-conductor segment between two gate-conductor segments each of which intersects an active-region structure at a channel region of a transistor. In some embodiments, the circuit cell includes a column of three terminal-conductor segments aligned along the Y-direction and bounded by bounded by the first power line and the second power line. The column of three terminal-conductor segments includes a middle terminal-conductor segment between two terminal-conductor segments each of which intersects an active-region structure at a source/drain region of a transistor. In some embodiments, a third power line or a routing line extending in the X-direction intersects one or both of the middle gate-conductor segment and the middle terminal-conductor segment. The inclusion of the middle gate-conductor segment reduces the parasitic capacitance of the gate terminals formed with the gate-conductor segments. The inclusion of the middle terminal-conductor segment reduces the parasitic capacitance of the source/drain terminals formed with the terminal-conductor segments. The inclusion of the third power line reduces the IR drop of the power grid net for delivering power to the circuit cell.

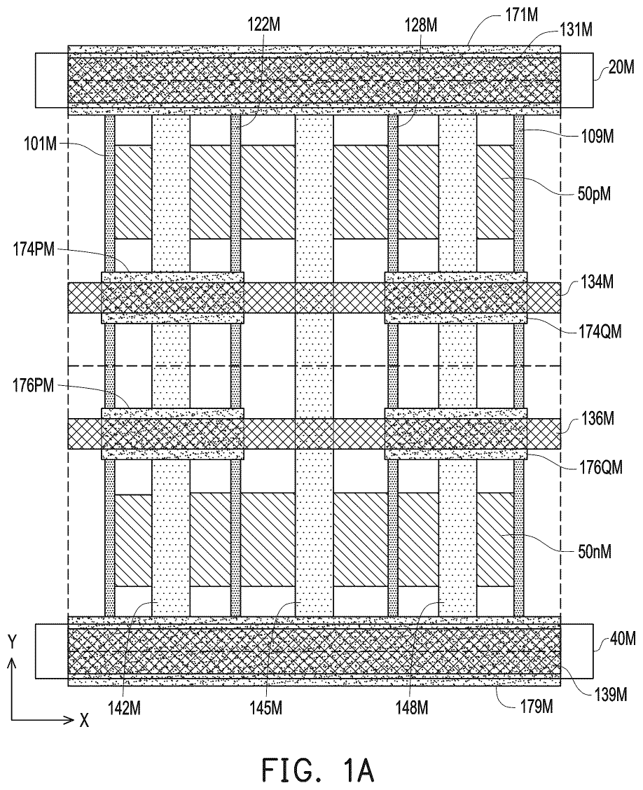

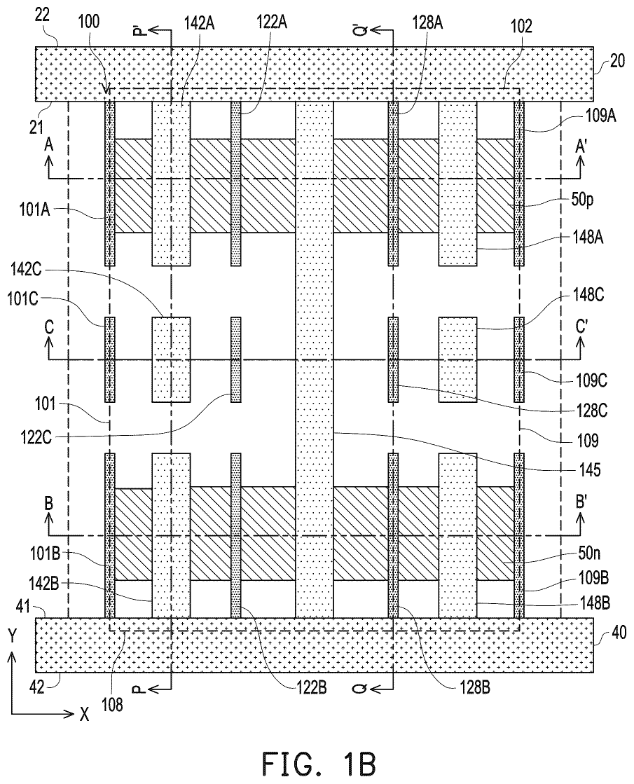

FIG. 1A is a layout diagram of an integrated circuit, in accordance with some embodiments. The layout diagram of FIG. 1A includes the layout pattern 50 pM for specifying a PMOS active-region structure extending in the X-direction, the layout pattern 50 nM for specifying an NMOS active-region structure extending in the X-direction, the layout patterns 122M and 128M for specifying gate-conductors extending in the Y-direction, the layout patterns 142M and 148M for specifying terminal-conductors extending in the Y-direction, and the layout patterns 101M and 109M for specifying dummy gate-conductors extending in the Y-direction. In the X-Y coordinate, the X-direction and the Y-direction are perpendicular to each other. The layout diagram of FIG. 1A also includes the layout patterns 20M and 40M for specifying power lines extending in the X-direction, the layout patterns 131M, 134M, 136M, and 139M for specifying the cutting of the gate-conductors and the cutting of the dummy gate-conductors, and the layout patterns 171M, 174PM, 174QM, 176PM, 176QM, and 179M for specifying the cutting of the terminal-conductors.

FIG. 1B is a schematic of an integrated circuit formed based on the layout diagram of FIG. 1A, in accordance with some embodiments. In FIG. 1B, the integrated circuit includes a circuit cell 100 having vertical cell boundaries 101 and 109 extending in the Y-direction and horizontal cell boundaries 102 and 108 extending in the X-direction. The circuit cell 100 includes a PMOS active-region structure 50p and an NMOS active-region structure 50n each extending in the X-direction. The circuit cell 100 includes power lines 20 and 40 each extending in the X-direction. The active-region structure adjacent to the power line 20 is the PMOS active-region structure 50p, and the active-region structure adjacent to the power line 40 is the NMOS active-region structure 50n. In some embodiments, the power line 20 is configured to be maintained at an upper supply voltage VCC, and the power line 40 is configured to be maintained at a lower supply voltage VSS, where the upper supply voltage VCC is higher than the lower supply voltage VSS. In some alternative embodiments, The active-region structure adjacent to the power line 20 is an NMOS active-region structure, and the active-region structure adjacent to the power line 40 is a PMOS active-region structure. In the alternative embodiments, the power line 20 is configured to be maintained at a lower supply voltage VSS, and the power line 40 is configured to be maintained at an upper supply voltage VCC.

The circuit cell 100 also includes gate-conductor segments 122A-122C and 128A-128C and dummy gate-conductor segments 101A-101C and 109A-109C. The circuit cell 100 includes terminal-conductor segments 142A-142C and 148A-148C and dummy gate-conductor segments 101A-101C and 109A-109C. The gate-conductor segments 122A-122C form a first column of three gate-conductor segments aligned along the Y-direction, in which the gate-conductor segment 122C is a middle gate-conductor segment between the other gate-conductor segments 122A and 122B. The gate-conductor segments 128A-128C form a second column of three gate-conductor segments aligned along the Y-direction, in which the gate-conductor segment 128C is a middle gate-conductor segment between the other gate-conductor segments 128A and 128B. The first column of three gate-conductor segments 122A-122C and the second column of three gate-conductor segments 128A-128C are each bounded by the horizontal cell boundary 102 and the horizontal cell boundary 108; that is, each of the first column and the second column do not extend across the horizontal cell boundaries 102 or 108. Furthermore, the horizontal cell boundary 102 overlaps with the power line 20 and the horizontal cell boundary 108 boundary overlaps with the power line 40.

In the implementation in FIG. 1B, the first column of three gate-conductor segments 122A-122C is bounded by the power line 20 and the power line 40, because the gate-conductor segment 122A does not overlap with the power line 20 and the gate-conductor segment 122B does not overlap with the power line 40. In some alternative implementations, the gate-conductor segment 122A extends across a first horizontal boundary 21 of the power line 20 but does not extend across a second horizontal boundary 22 of the power line 20, and consequently the first column of three gate-conductor segments 122A-122C is still bounded by the power line 20 and the power line 40. Similarly, in some alternative implementations, the gate-conductor segment 122B extends across a first horizontal boundary 41 of the power line 40 but does not extend across a second horizontal boundary 42 of the power line 40, and consequently the first column of three gate-conductor segments 122A-122C is still bounded by the power line 20 and the power line 40.

In the implementation in FIG. 1B, the second column of three gate-conductor segments 128A-128C is bounded by the power line 20 and the power line 40, because the gate-conductor segment 128A does not overlap with the power line 20 and the gate-conductor segment 128B does not overlap with the power line 40. In some alternative implementations, the gate-conductor segment 128A extends across a first horizontal boundary 21 of the power line 20 but does not extend across a second horizontal boundary 28 of the power line 20, and consequently the second column of three gate-conductor segments 128A-128C is still bounded by the power line 20 and the power line 40. Similarly, in some alternative implementations, the gate-conductor segment 128B extends across a first horizontal boundary 41 of the power line 40 but does not extend across a second horizontal boundary 42 of the power line 40, and consequently the second column of three gate-conductor segments 128A-128C is still bounded by the power line 20 and the power line 40.

In some embodiments, each of the gate-conductor segments 122A and 128A intersects the PMOS active-region structure 50p at a channel region of a PMOS transistor, and each of the gate-conductor segments 122B and 128B intersects the NMOS active-region structure 50n at a channel region of an NMOS transistor. In some embodiments, each of the PMOS active-region structure 50p and the NMOS active-region structure 50n includes one or more fin structures, and consequently, the PMOS transistors and the NMOS transistors formed with the active-region structures are finFET transistors. In some embodiments, each of the PMOS active-region structure 50p and the NMOS active-region structure 50n includes one or more nano-sheets, and consequently the PMOS transistors and the NMOS transistors formed with the active-region structures are nano-sheet transistors. In some embodiments, each of the PMOS active-region structure 50p and the NMOS active-region structure 50n includes one or more nano-wires, and consequently the PMOS transistors and the NMOS transistors formed with the active-region structures are nano-wire transistors.

The first column of three gate-conductor segments 122A-122C is formed based on the specification defined by the layout pattern 122M and the layout patterns 131M, 134M, 136M, and 139M in the layout diagram of FIG. 1A. The second column of three gate-conductor segments 128A-128C is formed based on the specification defined by the layout pattern 128M and the layout patterns 131M, 134M, 136M, and 139M in the layout diagram of FIG. 1A. The separation distance (along the Y-direction) between the gate-conductor segment 122A and the gate-conductor segment 122C or between the gate-conductor segment 128A and the gate-conductor segment 128C is determined by the width of the layout pattern 134M (along the Y-direction). Similarly, the separation distance (along the Y-direction) between the gate-conductor segment 122B and the gate-conductor segment 122C or between the gate-conductor segment 128B and the gate-conductor segment 128C is determined by the width of the layout pattern 136M (along the Y-direction).

The dummy gate-conductor segments 101A-101C aligned along the Y-direction at the vertical cell boundary 101 are formed based on the specification defined by the layout pattern 101M and the layout patterns 131M, 134M, 136M, and 139M in the layout diagram of FIG. 1A. The dummy gate-conductor segments 109A-109C aligned along the Y-direction at the vertical cell boundary 109 are formed based on the specification defined by the layout pattern 109M and the layout patterns 131M, 134M, 136M, and 139M in the layout diagram of FIG. 1A.

In FIG. 1B, the terminal-conductor segments 142A-142C form a first column of three terminal-conductor segments aligned along the Y-direction, in which the terminal-conductor segment 142C is a middle terminal-conductor segment between the other terminal-conductor segments 142A and 142B. The terminal-conductor segments 148A-148C form a second column of three terminal-conductor segments aligned along the Y-direction, in which the terminal-conductor segment 142C is a middle terminal-conductor segment between the other terminal-conductor segments 142A and 142B. The first column of three terminal-conductor segments 142A-142C and the second column of three terminal-conductor segments 148A-148C are each bounded by the horizontal cell boundary 102 and the horizontal cell boundary 108; that is, each of the first column and the second column does not extend across the horizontal cell boundaries 102 or 108. Furthermore, the horizontal cell boundary 102 overlaps with the power line 20 and the horizontal cell boundary 108 boundary overlaps with the power line 40.

In the implementation in FIG. 1B, the first column of three terminal-conductor segments 142A-142C is bounded by the power line 20 and the power line 40, because the terminal-conductor segment 142A does not overlap with the power line 20 and the terminal-conductor segment 142B does not overlap with the power line 40. In some alternative implementations, the terminal-conductor segment 142A extends across a first horizontal boundary 21 of the power line 20 but does not extend across a second horizontal boundary 22 of the power line 20, and consequently the first column of three terminal-conductor segments 142A-142C is still bounded by the power line 20 and the power line 40. Similarly, in some alternative implementations, the terminal-conductor segment 142B extends across a first horizontal boundary 41 of the power line 40 but does not extend across a second horizontal boundary 42 of the power line 40, and consequently the first column of three terminal-conductor segments 142A-142C is still bounded by the power line 20 and the power line 40.

In the implementation in FIG. 1B, the second column of three terminal-conductor segments 148A-148C is bounded by the power line 20 and the power line 40, because the terminal-conductor segment 148A does not overlap with the power line 20 and the terminal-conductor segment 148B does not overlap with the power line 40. In some alternative implementations, the terminal-conductor segment 148A extends across a first horizontal boundary 21 of the power line 20 but does not extend across a second horizontal boundary 28 of the power line 20, and consequently the second column of three terminal-conductor segments 148A-148C is still bounded by the power line 20 and the power line 40. Similarly, in some alternative implementations, the terminal-conductor segment 148B extends across a first horizontal boundary 41 of the power line 40 but does not extend across a second horizontal boundary 42 of the power line 40, and consequently the second column of three terminal-conductor segments 148A-148C is still bounded by the power line 20 and the power line 40.

The first column of three terminal-conductor segments 142A-142C is formed based on the specification defined by the layout pattern 142M and the layout patterns 171M, 174PM, 174QM, 176PM, 176QM, and 179M in the layout diagram of FIG. 1A. The second column of three terminal-conductor segments 148A-148C is formed based on the specification defined by the layout pattern 148M and the layout patterns 171M, 174PM, 174QM, 176PM, 176QM, and 179M in the layout diagram of FIG. 1A. The separation distance (along the Y-direction) between the terminal-conductor segment 142A and the terminal-conductor segment 142C is determined by the width of the layout pattern 174PM (along the Y-direction). The separation distance (along the Y-direction) between the terminal-conductor segment 148A and the terminal-conductor segment 148C is determined by the width of the layout pattern 174QM (along the Y-direction). Similarly, the separation distance (along the Y-direction) between the terminal-conductor segment 142B and the terminal-conductor segment 142C is determined by the width of the layout pattern 176PM (along the Y-direction). The separation distance (along the Y-direction) between the terminal-conductor segment 148B and the terminal-conductor segment 148C is determined by the width of the layout pattern 176QM (along the Y-direction).

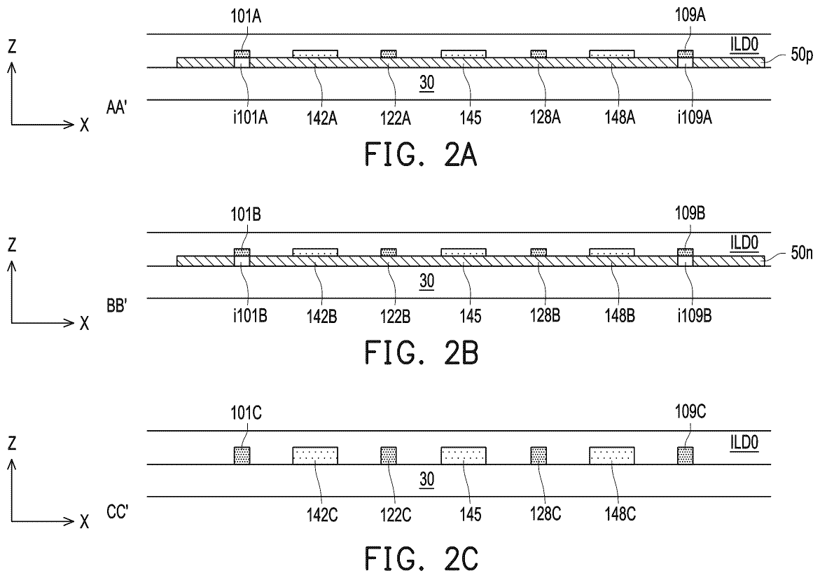

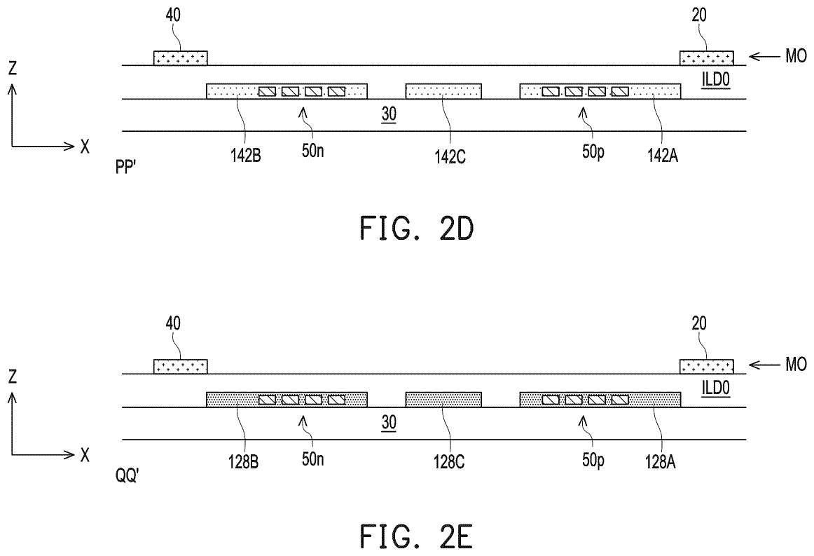

FIG. 2A is a cross-sectional view of the circuit cell 100 along the cutting plane AA′ as shown in FIG. 1A. In FIG. 2A, the PMOS active-region structure 50p is on the substrate 30. Each of the gate-conductor segments 122A and 128A intersects the PMOS active-region structure 50p at the channel region of a corresponding PMOS transistor. Each of the terminal-conductor segments 142A, 145 and 148A intersects the PMOS active-region structure 50p at the terminal region of at least one corresponding PMOS transistor. A terminal region of a PMOS transistor is either a source region or drain region of the PMOS transistor. In some embodiments, the active regions (such as the source region, the channel region, or the drain region) in the PMOS active-region structure 50p are isolated from the active regions in the adjacent cells by the boundary isolation region i101A under the dummy gate-conductor 101A and the boundary isolation region i109A under the dummy gate-conductor 109A. The gate-conductor segments 122A and 128A and the terminal-conductor segments 142A, 145 and 148A are each covered with the interlayer dielectric ILD0.

FIG. 2B is a cross-sectional view of the circuit cell 100 along the cutting plane BB′ as shown in FIG. 1A. In FIG. 2B, the NMOS active-region structure 50n is on the substrate 30. Each of the gate-conductor segments 122B and 128B intersects the NMOS active-region structure 50n at the channel region of a corresponding NMOS transistor. Each of the terminal-conductor segments 142B, 145 and 148B intersects the NMOS active-region structure 50n at the terminal region of at least one corresponding NMOS transistor. In some embodiments, the active regions (such as the source region, the channel region, or the drain region) in the NMOS active-region structure 50n are isolated from the active regions in the adjacent cells by the boundary isolation region i101B under the dummy gate-conductor 101B and the boundary isolation region i109B under the dummy gate-conductor 109B. The gate-conductor segments 122B and 128B and the terminal-conductor segments 142B, 145 and 148B are each covered with the interlayer dielectric ILD0.

The vertical cell boundaries 101 and 109 of the circuit cell 100 in FIG. 1B are identifiable with the boundary isolation regions in the integrated circuit. The boundary isolation region i101A under the dummy gate-conductor 101A (as shown in FIG. 2A) and the boundary isolation region i101B under the dummy gate-conductor 101A (as shown in FIG. 2B) are aligned vertically along the Y-direction and delineate a vertical cell boundary 101 of the circuit cell 10. The boundary isolation region i109A under the dummy gate-conductor 109A (as shown in FIG. 2A) and the boundary isolation region i109B under the dummy gate-conductor 109A (as shown in FIG. 2B) are aligned vertically along the Y-direction and delineate a vertical cell boundary 109 of the circuit cell 100.

FIG. 2C is a cross-sectional view of the circuit cell 100 along the cutting plane CC′ as shown in FIG. 1A. In FIG. 2C, each of the gate-conductor segments 122C and 128C extends in the Y-direction on the substrate 30, and each of the terminal-conductor segments 142C, 145 and 148C also extends in the Y-direction on the substrate 30. The gate-conductor segments 122C and 128C and the terminal-conductor segments 142C, 145 and 148C are each covered with the interlayer dielectric ILD0.

FIG. 2D is a cross-sectional view of the circuit cell 100 along the cutting plane PP′ as shown in FIG. 1A, in accordance with some embodiments. Each of the terminal-conductor segments 142A, 142C and 142B extends in the Y-direction on the substrate 30. The terminal-conductor segments 142A and 142B correspondingly intersect the PMOS active-region structure 50p and the NMOS active-region structure 50n. The power lines 20 and 40 extending in the X-direction are formed in the first metal layer (e.g., a metal layer MO) overlying the first interlayer dielectric ILD0 that covers the terminal-conductor segments 142A, 142C and 142B.

FIG. 2E is a cross-sectional view of the circuit cell 100 along the cutting plane QQ′ as shown in FIG. 1A. Each of the gate-conductor segments 128A, 128C, and 128B extends in the Y-direction on the substrate 30. The gate-conductor segments 128A and 128B correspondingly intersect the PMOS active-region structure 50p and the NMOS active-region structure 50n. The power lines 20 and 40 extending in the X-direction are formed in the first metal layer (e.g., a metal layer MO) overlying the first interlayer dielectric ILD0 that covers the gate-conductor segments 128A, 128C, and 128B.

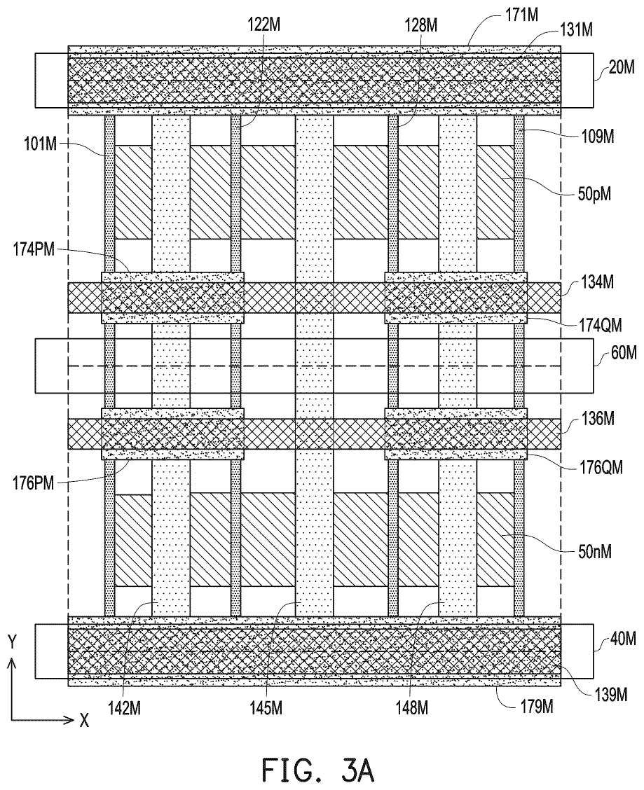

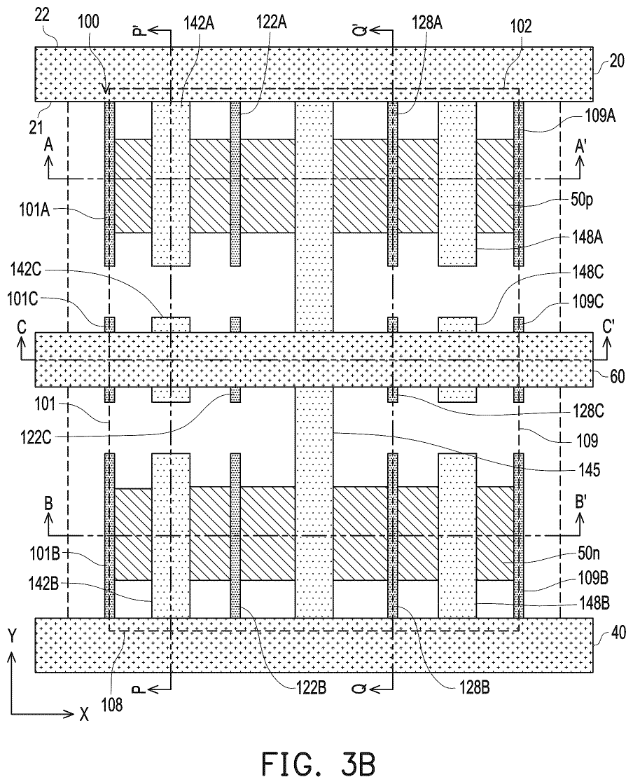

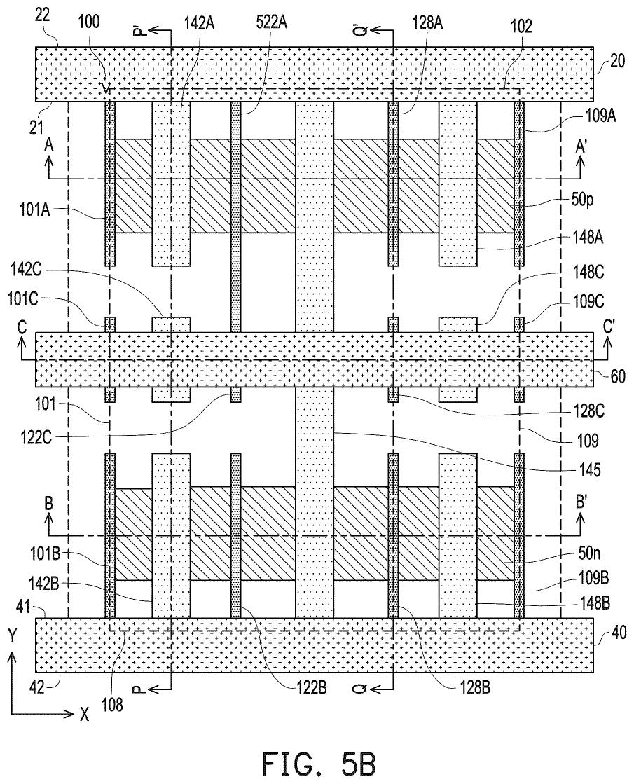

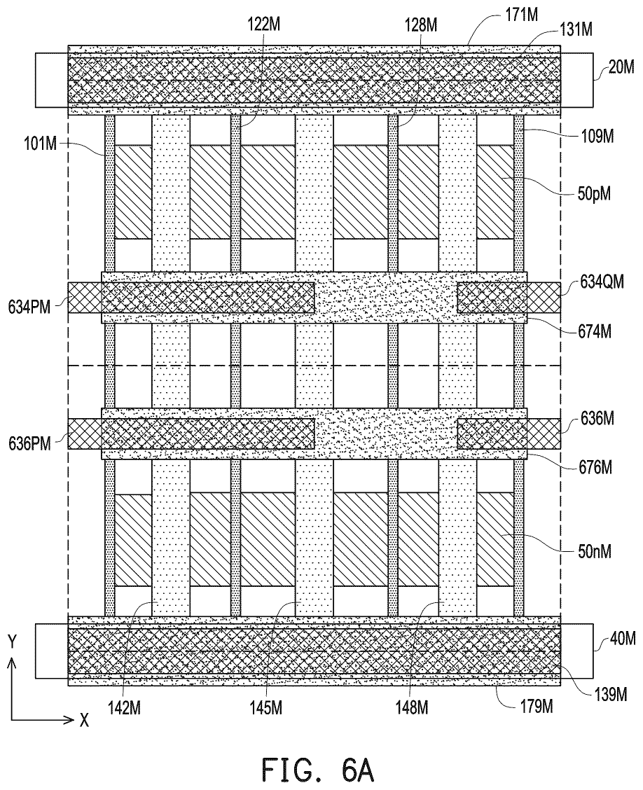

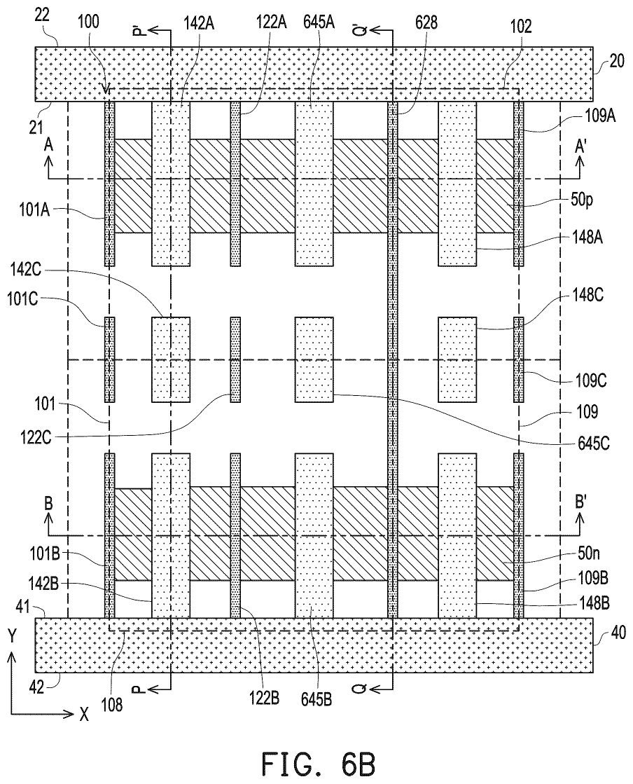

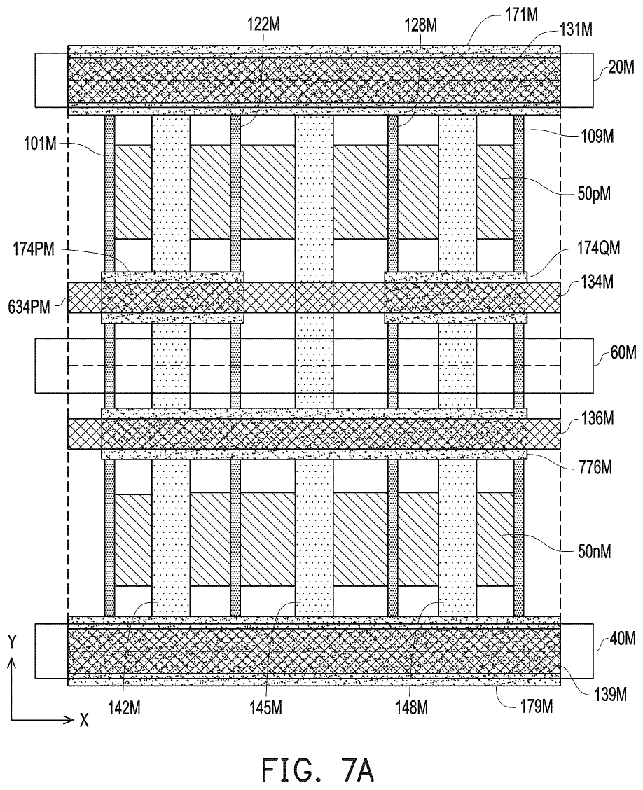

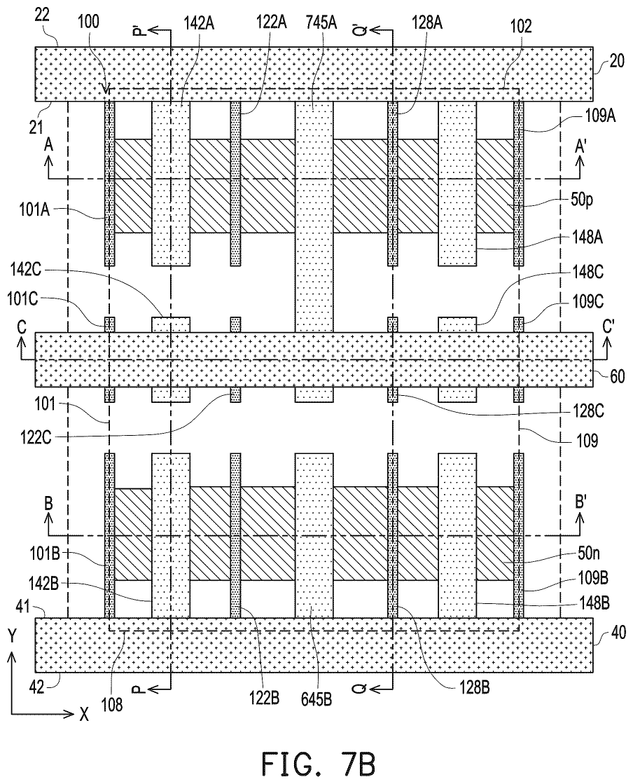

Some variations of the layout diagram in FIG. 1A are depicted in FIG. 3A, FIG. 5A, FIG. 6A, and FIG. 7A. Some variations of the integrated circuit formed based on the layout diagram of FIG. 1B are depicted in FIG. 3B, FIG. 5B, FIG. 6B, and FIG. 7B.

FIG. 3A is a layout diagram of an integrated circuit, in accordance with some embodiments. The layout diagram in FIG. 3A is modified from the layout diagram in FIG. 1A by adding the layout pattern 60M for specifying a power line extending in the X-direction. The layout pattern 60M extending in the X-direction is between the layout patterns 134M and 136M for specifying the cutting of the gate-conductors. The added power line as specified by the layout pattern 60M reduces the IR drop of the power grid net for delivering power to the circuit cell.

FIG. 3B is a schematic of an integrated circuit formed based on the layout diagram of FIG. 3A, in accordance with some embodiments. The integrated circuit in FIG. 3B is modified from the integrated circuit in FIG. 1B by adding a power line 60 extending in the X-direction. The power line 60 intersects the gate-conductor segments 122C and 128C, the terminal-conductor segments 142C and 148C, and the dummy gate-conductor segments 101C and 109C. In some embodiments, the power line 60 is connected to the terminal-conductor segment 145 through a via-connector.

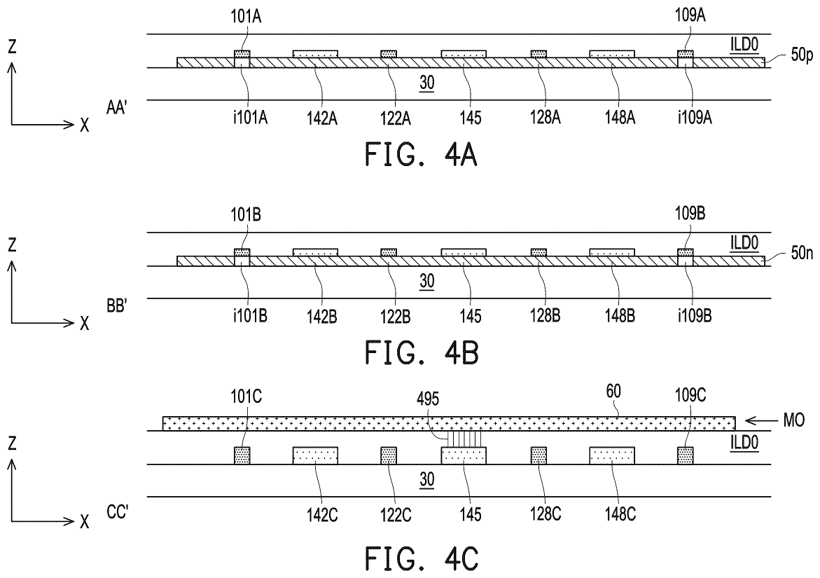

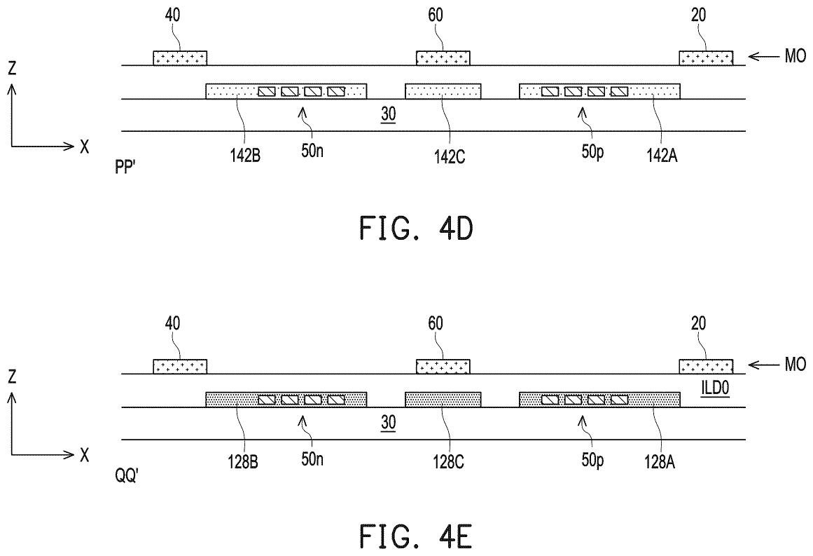

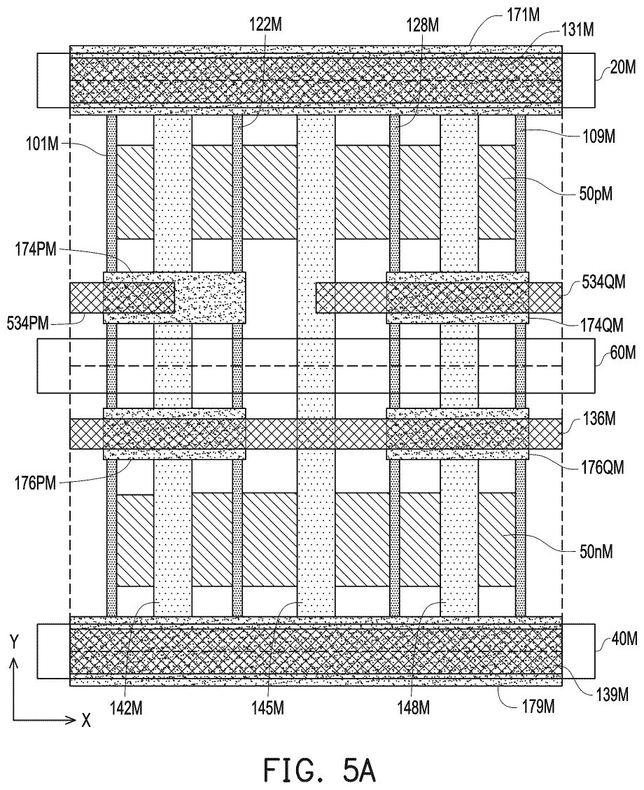

FIG. 4A-4C are cross-sectional views of the circuit cell in FIG. 3B along the cutting planes AA′, BB′, and CC′ correspondingly. The cross-sectional view in FIG. 4A is the same as the cross-sectional view in FIG. 2A, and the cross-sectional view in FIG. 4B is the same as the cross-sectional view in FIG. 2B. The cross-sectional view in FIG. 4C is modified from the cross-sectional view in FIG. 2C by adding the power line 60 extending in the X-direction in the first metal layer (e.g., a metal layer MO) overlying the first interlayer dielectric ILD0. In some embodiments, the power line 60 is connected to the terminal-conductor segment 145 through a via-connector 495 passing through the interlayer dielectric ILD0 underneath the first metal layer.

FIG. 4D-4E are cross-sectional views of the circuit cell in FIG. 3B along the cutting planes PP′ and QQ′ correspondingly. The cross-sectional view in FIG. 4D is modified from the cross-sectional view in FIG. 2D by adding the power line 60 in the first metal layer (e.g., a metal layer MO) overlying the first interlayer dielectric ILD0. The power line 60 extending in the X-direction is directly above the terminal-conductor segment 142C. The cross-sectional view in FIG. 4E is modified from the cross-sectional view in FIG. 2E by adding the power line 60 in the first metal layer (e.g., a metal layer MO) overlying the first interlayer dielectric ILD0. The power line 60 extending in the X-direction is directly above the gate-conductor segment 128C.

FIG. 5A is a layout diagram of an integrated circuit, in accordance with some embodiments. The layout diagram in FIG. 5A is modified from the layout diagram in FIG. 3A. The modification includes substituting the layout pattern 134M in FIG. 3A with the layout pattern 534PM and 534QM in FIG. 5A. The layout pattern 534PM specifies the cutting of the dummy gate-conductor specified by the layout patterns 101M. The layout pattern 534QM specifies the cutting of the gate-conductor specified by the layout patterns 128M and the cutting of the dummy gate-conductor specified by the layout patterns 109M. Because of the layout pattern 534PM and 534QM, the gate-conductor specified by the layout patterns 128M is cut into two segments, and one of the two segments extends across the power line 60, which enables one gate-conductor segment to be connected to the power line 60.

FIG. 5B is a schematic of an integrated circuit formed based on the layout diagram of FIG. 5A, in accordance with some embodiments. The integrated circuit in FIG. 5B is modified from the integrated circuit in FIG. 3B. The modification includes substituting the gate-conductor segments 122A-122C in FIG. 3B with the gate-conductor segments 522A and 522B in FIG. 5B. The gate-conductor segments 522A and 522B form a column of two gate-conductor segments aligned along the Y-direction and bounded by the power lines 20 and 40. In some embodiments, the gate-conductor segment 522A is connected to the power line 60 through a via-connector passing through the interlayer dielectric ILD0 underneath the first metal layer. In some embodiments, the power line 60 is substituted with a routing line (which is similarly specified by the layout pattern 60M in FIG. 5A), and the gate-conductor segment 522A is connected to the routing line through a via-connector passing through the interlayer dielectric ILD0 underneath the first metal layer.

FIG. 6A is a layout diagram of an integrated circuit, in accordance with some embodiments. The layout diagram in FIG. 6A is modified from the layout diagram in FIG. 1A. The modification includes substituting the layout pattern 134M in FIG. 1A with the layout patterns 634PM and 634QM in FIG. 6A, substituting the layout pattern 136M in FIG. 1A with the layout patterns 636PM and 636QM in FIG. 6A, substituting the layout patterns 174PM and 174QM in FIG. 1A with the layout pattern 674M in FIG. 6A, and substituting the layout patterns 176PM and 176QM in FIG. 1A with the layout pattern 676M in FIG. 6A. The layout patterns 634PM and 636PM specify the cutting of the dummy gate-conductor specified by the layout patterns 101M and the cutting of the gate-conductor specified by the layout patterns 122M. The layout patterns 634QM and 636QM specify the cutting of the dummy gate-conductor specified by the layout patterns 109M. The layout patterns 674M and 676M specify the cutting of the terminal-conductors defined by layout patterns 142M, 145M, and 148M. Because of the layout patterns 634PM and 634QM and the layout patterns 636PM and 636QM, the gate-conductor specified by the layout patterns 128M is not cut in the area between the PMOS active-region structure 50p and the NMOS active-region structure 50n.

FIG. 6B is a schematic of an integrated circuit formed based on the layout diagram of FIG. 6A, in accordance with some embodiments. The integrated circuit in FIG. 6B is modified from the integrated circuit in FIG. 1B. The modification includes substituting the gate-conductor segments 128A-128C in FIG. 1B with the gate-conductor segment 628 in

FIG. 6B, and substituting the terminal-conductor segment 145 with the terminal-conductor segments 645A-645C. The gate-conductor segment 628 constitutes a column of one gate-conductor segment aligned along the Y-direction and bounded by the power lines 20 and 40. Because the gate-conductor segment 628 extends across both the PMOS active-region structure 50p and the NMOS active-region structure 50n, the gate terminals of a PMOS transistor and an NMO transistor are connected together in the circuit cell.

FIG. 7A is a layout diagram of an integrated circuit, in accordance with some embodiments. The layout diagram in FIG. 7A is modified from the layout diagram in FIG. 3A. The modification includes substituting the layout patterns 176PM and 176QM in FIG. 1A with the layout pattern 776M in FIG. 7A. The layout pattern 776M specifics the cutting of the terminal-conductors defined by layout patterns 142M, 145M, and 148M. Because of the layout pattern 776M, the terminal-conductor specified by the layout patterns 145M is cut into two segments, which enables one of the two segments to be connected to the power line 60 and another of the two segments to be connected to the power line 60.

FIG. 7B is a schematic of an integrated circuit formed based on the layout diagram of FIG. 7A, in accordance with some embodiments. The integrated circuit in FIG. 7B is modified from the integrated circuit in FIG. 3B. The modification includes substituting the terminal-conductor segment 145 with the terminal-conductor segments 745A and 745B. The terminal-conductor segments 745A and 745B form a column of two terminal-conductor segments aligned along the Y-direction and bounded by the power lines 20 and 40. In some embodiments, the terminal-conductor segment 745A is connected to the power line 60 through a via-connector passing through the interlayer dielectric ILD0 underneath the first metal layer. In some embodiments, the power line 60 is substituted with a routing line (which is similarly specified by the layout pattern 60M in FIG. 7A), and the terminal-conductor segment 745A is connected to the routing line through a via-connector passing through the interlayer dielectric ILD0 underneath the first metal layer.

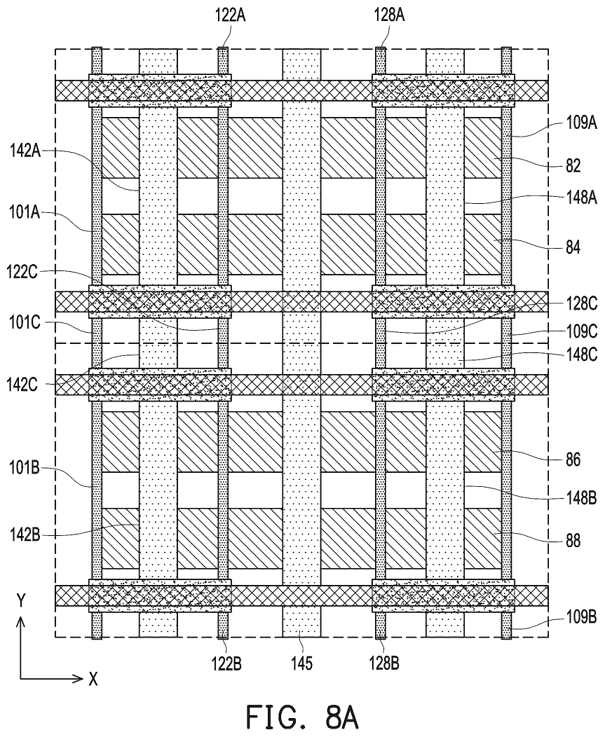

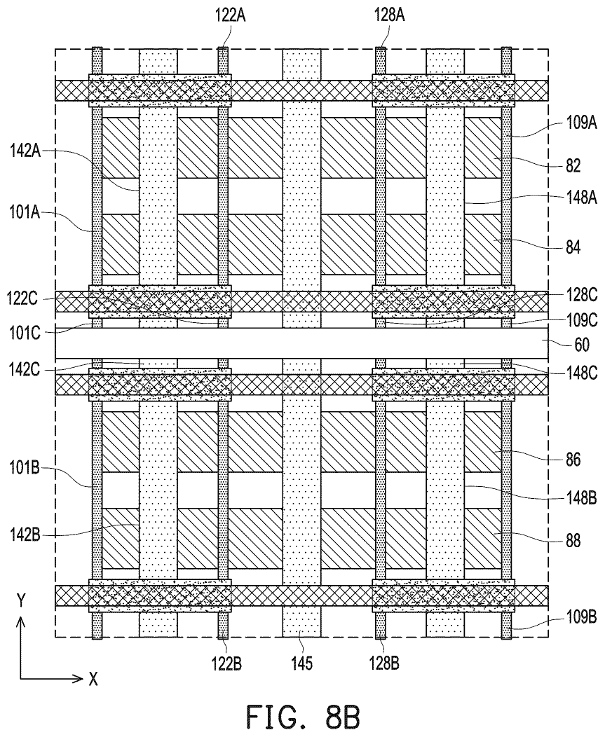

In addition to the integrated circuits as shown in depicted in FIG. 1B, FIG. 3B, FIG. 5B, FIG. 6B, and FIG. 7B, other variations of the integrated circuits are shown schematically in FIGS. 8A-8B.

FIG. 8A is a schematic of an integrated circuit which is a variation of the integrated circuit in FIG. 1B, in accordance with some embodiments. The integrated circuit in FIG. 8A includes active-region structures 82, 84, 86, and 88 extending in the X-direction. Each of the gate-conductor segments 122A and 128A intersects the active-region structures 82 and 84, each of the terminal-conductor segments 142A, 145, and 148A also intersects the active-region structures 82 and 84. Each of the gate-conductor segments 122B and 128B interacts the active-region structures 86 and 88, each of the terminal-conductor segments 142B, 145, and 148B also intersects the active-region structures 86 and 88. In some embodiments, each of the active-region structures 82 and 86 is a PMOS active-region structure, and each of the active-region structures 84 and 88 is an NMOS active-region structure. In some embodiments, each of the active-region structures 82 and 88 is a PMOS active-region structure, and each of the active-region structures 84 and 86 is an NMOS active-region structure. Because of the four active-region structures 82, 84, 86, and 88, two rows of PMOS transistors and two rows of NMOS transistors are implemented in a circuit cell.

FIG. 8B is a schematic of an integrated circuit which is a variation of the integrated circuit in FIG. 8A, in accordance with some embodiments. The integrated circuit in FIG. 8B is modified from integrated circuit in FIG. 8A by adding a power line 60 extending in the X-direction in a first metal layer (e.g., a metal layer MO) overlying the first interlayer dielectric ILD0 (e.g. ILD0 in FIG. 4C). The power line 60 intersects the gate-conductor segments 122C and 128C, the terminal-conductor segments 142C and 148C, and the dummy gate-conductor segments 101C and 109C. In some embodiments, the power line 60 is connected to the terminal-conductor segment 145 through a via-connector. Similar to the circuit cell in FIG. 8A, the circuit cell in FIG. 8B also includes two rows of PMOS transistors and two rows of NMOS transistors.

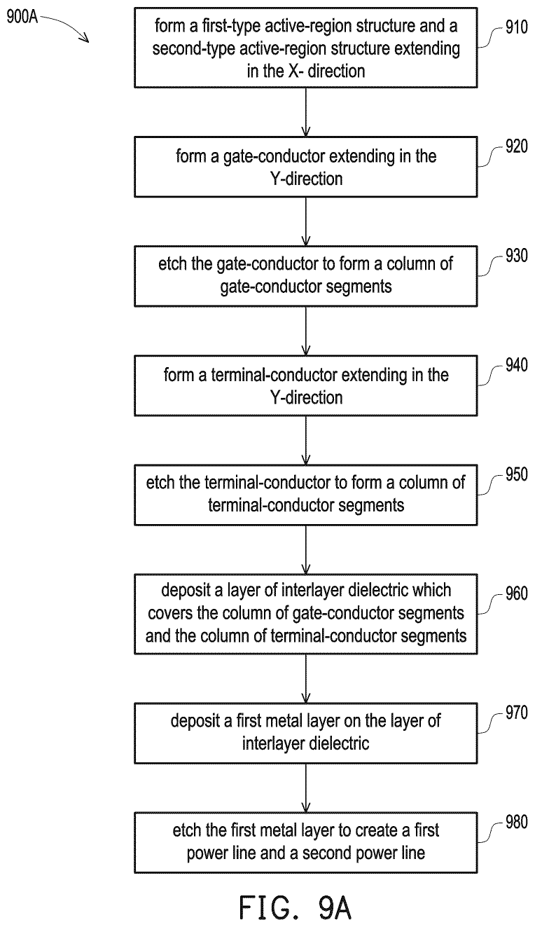

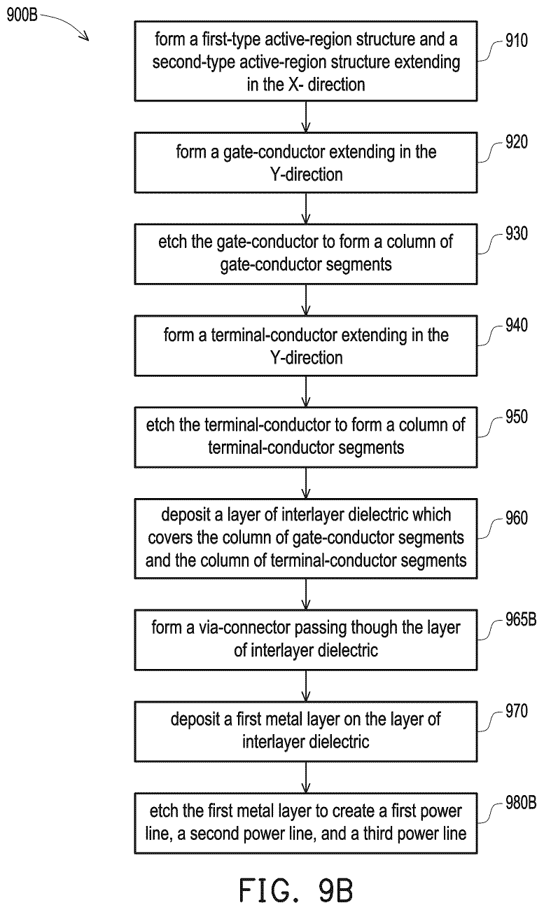

FIG. 9A is a flowchart of a method 900A of manufacturing an integrated circuit, in accordance with some embodiments. The sequence in which the operations of method 900A are depicted in FIG. 9A is for illustration only; the operations of method 900A are capable of being executed in sequences that differ from that depicted in FIG. 9A. It is understood that additional operations may be performed before, during, and/or after the method 900A depicted in FIG. 9A, and that some other processes may only be briefly described herein.

In operation 910 of method 900A, a first-type active-region structure and a second-type active-region structure extending in the X-direction direction are fabricated on a substrate. The channel region, the source region, and the drain region of at least one first-type transistor are formed with the first-type active-region structure. The channel region, the source region, and the drain region of at least one second-type transistor are formed with the second-type active-region structure. In some embodiments, the first-type active-region structure is a PMOS active-region structure, and the second-type active-region structure is an NMOS active-region structure. In some embodiments, the first-type active-region structure is an NMOS active-region structure, and the second-type active-region structure is a PMOS active-region structure. In the example embodiments of FIG. 1B and FIG. 2A-2E, the PMOS active-region structure 50p and the NMOS active-region structure 50n are fabricated on a substrate 30.

In operation 920 of method 900A, gate-conductors extending in the Y-direction are formed. Then, in operation 930 of method 900A, at least one gate-conductor is etched to form a column of gate-conductor segments. In the example embodiments of FIG. 1B and FIG. 2A-2E, two gate-conductors intersecting the PMOS active-region structure 50p and the NMOS active-region structure 50n are formed. Each of the two gate-conductors is specified by one of the layout patterns 122M and 128M (as shown in FIG. 1A). Then, the gate-conductors specified by the layout pattern 122M are etched to form the gate-conductor segments 122A, 122C, and 122B aligned along the Y-direction in a first column, and the gate-conductors specified by the layout pattern 128M are etched to form the gate-conductor segments 128A, 128C, and 128B aligned along the Y-direction in a second column.

In operation 940 of method 900A, terminal-conductors extending in the Y-direction are formed. Then, in operation 950 of method 900A, at least one terminal-conductor is etched to form a column of terminal-conductor segments. In the example embodiments of FIG. 1B and FIG. 2A-2E, three terminal-conductors intersecting the PMOS active-region structure 50p and the NMOS active-region structure 50n are formed. Each of the two terminal-conductors is specified by one of the layout patterns 142M, 145M, and 148M (as shown in FIG. 1A). Then, the terminal-conductors specified by the layout pattern 142M are etched to form the terminal-conductor segments 142A, 142C, and 142B aligned along the Y-direction in a first column, and the terminal-conductors specified by the layout pattern 148M are etched to form the terminal-conductor segments 148A, 148C, and 148B aligned along the Y-direction in a second column.

In operation 960 of method 900A, a layer of interlayer dielectric is deposited to cover the column of terminal-conductor segments and the column of terminal-conductor segments. In the example embodiments of FIG. 1B and FIG. 2A-2E, the interlayer dielectric ILD0 is deposited to cover the gate-conductor segments 122A-122C and 128A-128C and the terminal-conductor segments 142A-142C and 148A-148C. After operation 960, the process proceeds to operation 970.

In operation 970 of method 900A, a first metal layer is deposited on the layer of interlayer dielectric. Then, in operation 980 of method 900A, the first metal layer is etched to create a first power line and a second power line. In the example embodiments of FIG. 1B and FIG. 2A-2E, the metal layer MO is deposited on the interlayer dielectric ILD0. Subsequently, the metal layer MO is etched to create the power lines 20 and 40 extending in the X-direction.

FIG. 9B is a flowchart of a method 900B of manufacturing an integrated circuit, in accordance with some embodiments. The sequence in which the operations of method 900B are depicted in FIG. 9B is for illustration only; the operations of method 900B are capable of being executed in sequences that differ from that depicted in FIG. 9B. It is understood that additional operations may be performed before, during, and/or after the method 900B depicted in FIG. 9B, and that some other processes may only be briefly described herein.

The flowchart in FIG. 9B is modified from the flowchart in FIG. 9A. The modification includes adding operation 965B between operations 960 and 970. The modification also includes substituting operation 980 of FIG. 9A with operation 980B of FIG. 9B. In FIG. 9B, the process flow from operation 910 to operation 960 of the method 900B is the same as the process flow from operation 910 to operation 960 of the method 900A in FIG. 9A. In the method 900B, the process flow after operation 960 is different from that in the method 900A of FIG. 9A. Specifically, in the method 900B, after operation 960, the process proceeds to operation 965B.

In operation 965B of method 900B, one or more via-connectors passing though the layer of interlayer dielectric are fabricated. In the example embodiments of FIG. 3B and FIG. 4A-4E, the via-connector 495 passing through the interlayer dielectric ILD0 is fabricated. After operation 965B, the process proceeds to operation 970.

In operation 970 of method 900B, a first metal layer is deposited on the layer of interlayer dielectric. Then, in operation 980B of method 900B, the first metal layer is etched to create a first power line and a second power line. In the example embodiments of FIG. 3B and FIG. 4A-4E, the metal layer MO is deposited on the interlayer dielectric ILD0. Subsequently, the metal layer MO is etched to create the power lines 20, 40, and 60 extending in the X-direction. After the power line 60 is fabricated, as shown in FIG. 4C, the via-connector 495 connects the power line 60 to the terminal-conductor segment 145.

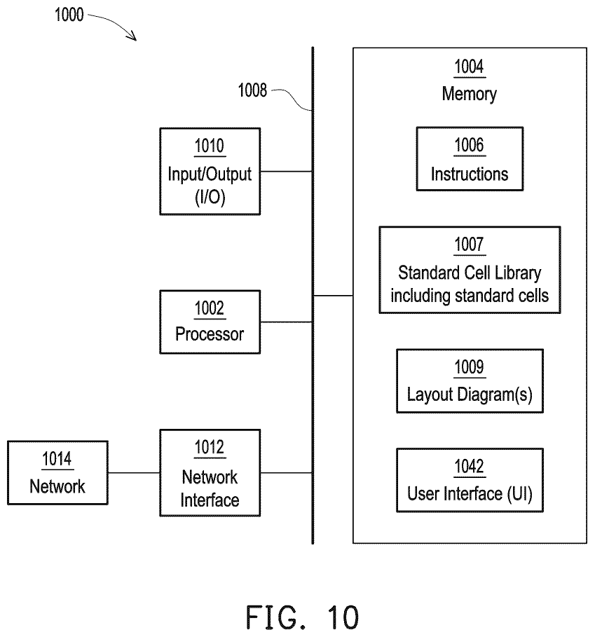

FIG. 10 is a block diagram of an electronic design automation (EDA) system 1000 in accordance with some embodiments.

In some embodiments, EDA system 1000 includes an automatic placement and routing (APR) system. Methods described herein of designing layout diagrams represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable storage medium 1004. Storage medium 1004, amongst other things, is encoded with, i.e., stores, computer program code 1006, i.e., a set of executable instructions. Execution of instructions 1006 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable storage medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable storage medium 1004 are capable of connecting to external elements via network 1014. Processor 1002 is configured to execute computer program code 1006 encoded in computer-readable storage medium 1004 in order to cause system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable storage medium 1004 is an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, storage medium 1004 stores computer program code 1006 configured to cause system 1000 (where such execution represents (at least in part) the EDA tool) to be usable for performing a portion or all of the noted processes and/or methods. In one or more embodiments, storage medium 1004 also stores information which facilitates performing a portion or all of the noted processes and/or methods. In one or more embodiments, storage medium 1004 stores library 1007 of standard cells including such standard cells as disclosed herein. In one or more embodiments, storage medium 1004 stores one or more layout diagrams 1009 corresponding to one or more layouts disclosed herein.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a user interface (UI) through I/O interface 1010. The information is stored in computer-readable medium 1004 as UI 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

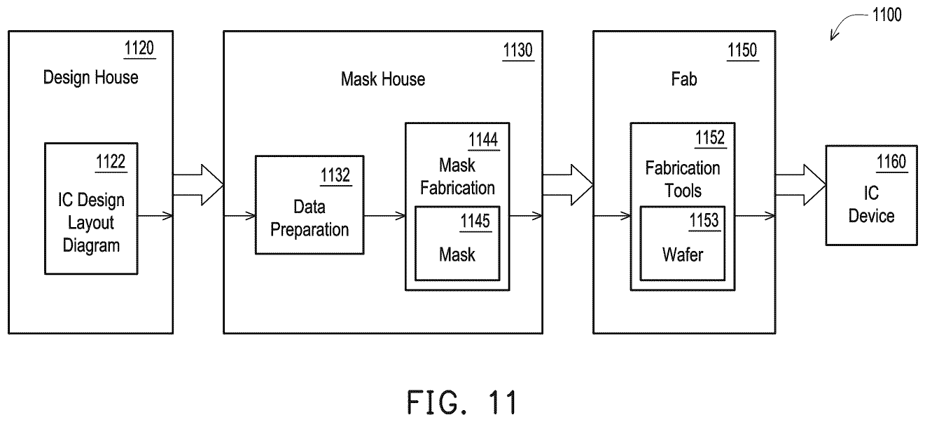

FIG. 11 is a block diagram of an integrated circuit (IC) manufacturing system 1100, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (fab) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122. IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (RDF). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for photolithographic implementation effects during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

An aspect of the present disclosure relates to an integrated circuit. The integrated circuit includes a first-type active-region structure and a second-type active-region structure extending in a first direction. The integrated circuit also includes a first power line and a second power line extending in the first direction. The integrated circuit further includes a column of three gate-conductor segments aligned along a second direction and bounded by the first power line and the second power line. The three gate-conductor segments includes a middle gate-conductor segment between a first gate-conductor segment and a second gate-conductor segment, the first gate-conductor segment intersecting the first-type active-region structure at a channel region of a first-type transistor and the second gate-conductor segment intersecting the second-type active-region structure at a channel region of a second-type transistor. The second direction is perpendicular to the first direction.

Another aspect of the present disclosure also relates to an integrated circuit. The integrated circuit includes a first-type active-region structure and a second-type active-region structure extending in a first direction, a first power line and a second power line extending in the first direction, and a circuit cell having a first horizontal cell boundary and a second horizontal cell boundary extending in the first direction. The first horizontal cell boundary overlaps with the first power line and the second horizontal cell boundary overlaps with the second power line. The circuit cell includes a column of three terminal-conductor segments aligned along a second direction and bounded by the first horizontal cell boundary and the second horizontal cell boundary. The second direction is perpendicular to the first direction. The three terminal-conductor segments include a middle terminal-conductor segment between a first terminal-conductor segment and a second terminal-conductor segment. The first terminal-conductor segment intersecting the first-type active-region structure at a terminal region of a first-type transistor. The second terminal-conductor segment intersecting the second-type active-region structure at a terminal region of a second-type transistor. Each terminal region is either a source region or a drain region.

Another aspect of the present disclosure relates to a method of fabricating an integrated circuit. The method includes forming a first-type active-region structure and a second-type active-region structure on a substrate extending in a first direction, forming a gate-conductor extending in a second direction which is perpendicular to the first direction, and forming a column of three gate-conductor segments from the gate-conductor. The column of three gate-conductor segments includes a middle gate-conductor segment between a first gate-conductor segment and a second gate-conductor segment, the first gate-conductor segment intersecting the first-type active-region structure at a channel region of a first-type transistor and the second gate-conductor segment intersecting the second-type active-region structure at a channel region of a second-type transistor. The method also includes depositing a layer of interlayer dielectric which covers the column of three gate-conductor segments, the first-type active-region structure, and the second-type active-region structure. The method further includes depositing a first metal layer on the layer of interlayer dielectric, and forming a first power line and a second power line extending in the first direction in the first metal layer. The column of three gate-conductor segments is bounded by the first power line and the second power line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit comprising:
a first-type active-region structure and a second-type active-region structure extending in a first direction;
a first power line and a second power line extending in the first direction; and
a column of three gate-conductor segments aligned along a second direction and bounded by the first power line and the second power line, wherein the three gate-conductor segments include a middle gate-conductor segment between a first gate-conductor segment and a second gate-conductor segment, the first gate-conductor segment intersecting the first-type active-region structure at a channel region of a first-type transistor and the second gate-conductor segment intersecting the second-type active-region structure at a channel region of a second-type transistor, and wherein the second direction is perpendicular to the first direction.

2. The integrated circuit of claim 1, further comprising:
a third power line extending in the second direction, the third power line intersecting the middle gate-conductor segment.

3. The integrated circuit of claim 1, further comprises:
a column of three terminal-conductor segments aligned along the second direction and bounded by the first power line and the second power line, wherein the three terminal-conductor segments include a middle terminal-conductor segment between a first terminal-conductor segment and a second terminal-conductor segment, the first terminal-conductor segment intersecting the first-type active-region structure at a terminal region of a first-type transistor, wherein the second terminal-conductor segment intersecting the second-type active-region structure at a terminal region of a second-type transistor, and wherein each terminal region is either a source region or a drain region.

4. The integrated circuit of claim 3, further comprising:
a third power line extending in the second direction, the third power line intersecting each of the middle terminal-conductor segment and the middle gate-conductor segment.

5. The integrated circuit of claim 1, further comprising:
a column of two terminal-conductor segments aligned along the second direction and bounded by the first power line and the second power line, wherein the column of two terminal-conductor segments includes a first terminal-conductor segment intersecting the first-type active-region structure at a terminal region of a first-type transistor, and wherein the column of two terminal-conductor segments includes a second terminal-conductor segment intersecting the second-type active-region structure at a terminal region of a second-type transistor.

6. The integrated circuit of claim 5, further comprising:
a third power line extending in the second direction, the third power line intersecting the first terminal-conductor segment; and
a via-connector connecting the third power line with the first terminal-conductor segment.

7. The integrated circuit of claim 1, further comprising:
a terminal-conductor segment extending in the second direction and bounded by the first power line and the second power line, wherein the terminal-conductor segment intersects both the first-type active-region structure and the second-type active-region structure.

8. The integrated circuit of claim 7, further comprising:
a third power line extending in the second direction between the first power line and the second power line; and
a via-connector connecting the third power line with the terminal-conductor segment.

9. An integrated circuit comprising:
a first-type active-region structure and a second-type active-region structure extending in a first direction;
a first power line and a second power line extending in the first direction; and
a circuit cell having a first horizontal cell boundary and a second horizontal cell boundary extending in the first direction, wherein the first horizontal cell boundary overlaps with the first power line and the second horizontal cell boundary overlaps with the second power line, and wherein the circuit cell comprises:
a column of three terminal-conductor segments aligned along a second direction and bounded by the first horizontal cell boundary and the second horizontal cell boundary, the second direction being perpendicular to the first direction, wherein the three terminal-conductor segments include a middle terminal-conductor segment between a first terminal-conductor segment and a second terminal-conductor segment, wherein the first terminal-conductor segment intersecting the first-type active-region structure at a terminal region of a first-type transistor, wherein the second terminal-conductor segment intersecting the second-type active-region structure at a terminal region of a second-type transistor, and wherein each terminal region is either a source region or a drain region.

10. The integrated circuit of claim 9, further comprising:
a third power line extending in the second direction, the third power line intersecting the middle terminal-conductor segment.

11. The integrated circuit of claim 9, wherein the circuit cell further comprises:
a column of three gate-conductor segments aligned along a second direction and bounded by the first horizontal cell boundary and the second horizontal cell boundary, wherein the three gate-conductor segments include a middle gate-conductor segment between a first gate-conductor segment and a second gate-conductor segment, the first gate-conductor segment intersecting the first-type active-region structure at a channel region of a first-type transistor and the second gate-conductor segment intersecting the second-type active-region structure at a channel region of a second-type transistor, and wherein the second direction is perpendicular to the first direction.

12. The integrated circuit of claim 11, further comprising:
a third power line extending in the second direction, the third power line intersecting each of the middle terminal-conductor segment and the middle gate-conductor segment.

13. The integrated circuit of claim 11, further comprising:
a first isolation region and a second isolation region in the first-type active-region structure;
a third isolation region and a fourth isolation region in the second-type active-region structure, wherein the third isolation region in the second-type active-region structure and the first isolation region in the first-type active-region structure are aligned vertically along a second direction and delineates a first vertical cell boundary of the circuit cell, and wherein the fourth isolation region in the second-type active-region structure and the second isolation region in the first-type active-region structure are aligned vertically along the second direction and delineates a second vertical cell boundary of the circuit cell; and
wherein the column of three terminal-conductor segments and the column of three gate-conductor segments are between the first vertical cell boundary and the second vertical cell boundary.

14. The integrated circuit of claim 9, wherein the circuit cell further comprises:
a column of two gate-conductor segments aligned along the second direction and bounded by the first horizontal cell boundary and the second horizontal cell boundary, wherein the column of two gate-conductor segments includes a first gate-conductor segment and a second gate-conductor segment, wherein the first gate-conductor segment intersects the first-type active-region structure at a channel region of a first-type transistor, and wherein the second gate-conductor segment intersects the second-type active-region structure at a channel region of a second-type transistor.

15. The integrated circuit of claim 9, wherein the circuit cell further comprises:
a gate-conductor segment extending in the second direction and bounded by the first horizontal cell boundary and the second horizontal cell boundary, wherein the gate-conductor segment intersects both the first-type active-region structure and the second-type active-region structure.

16. A method comprising:
forming a first-type active-region structure and a second-type active-region structure on a substrate extending in a first direction;
forming a gate-conductor extending in a second direction which is perpendicular to the first direction;
forming a column of three gate-conductor segments from the gate-conductor, wherein the column of three gate-conductor includes a middle gate-conductor segment between a first gate-conductor segment and a second gate-conductor segment, the first gate-conductor segment intersecting the first-type active-region structure at a channel region of a first-type transistor and the second gate-conductor segment intersecting the second-type active-region structure at a channel region of a second-type transistor;
depositing a layer of interlayer dielectric which covers the column of three gate-conductor segments, the first-type active-region structure, and the second-type active-region structure;
depositing a first metal layer on the layer of interlayer dielectric; and
forming a first power line and a second power line extending in the first direction in the first metal layer, wherein the column of three gate-conductor segments is bounded by the first power line and the second power line.

17. The method of claim 16, further comprising:
forming a third power line extending in the first direction in the first metal layer, wherein the third power line intersects the middle gate-conductor segment.

18. The method of claim 16, further comprising:
forming a terminal-conductor extending in the second direction; and
forming a column of three terminal-conductor segments from the terminal-conductor, wherein the column of three terminal-conductor segments includes a middle terminal-conductor segment between a first terminal-conductor segment and a second terminal-conductor segment, the first terminal-conductor segment intersecting the first-type active-region structure at a terminal region of a first-type transistor and the second terminal-conductor segment intersecting the second-type active-region structure at a terminal region of a second-type transistor.

19. The method of claim 18, further comprising:
forming a third power line extending in the first direction in the first metal layer, wherein the third power line intersects both the middle gate-conductor segment and the middle terminal-conductor segment.

20. The method of claim 16, further comprising:
forming a terminal-conductor extending in the second direction;
forming a column of two terminal-conductor segments from the terminal-conductor, wherein the column of two terminal-conductor segments includes a first terminal-conductor segment and a second terminal-conductor segment, the first terminal-conductor segment intersecting the first-type active-region structure at a terminal region of a first-type transistor and the second terminal-conductor segment intersecting the second-type active-region structure at a terminal region of a second-type transistor; and
forming a third power line extending in the first direction in the first metal layer, wherein the third power line intersects both the middle gate-conductor segment and the first terminal-conductor segment.
